(19) United States
(12) Patent Application Publication
(10) Pub. No.: US 2024/0348015 A1
(43) Pub. Date: Oct. 17, 2024

(54) SURFACE-COUPLED INTEGRATED-CAVITY SEMICONDUCTOR LASER

(71) Applicant: California Institute of Technology, Pasadena, CA (US)

(72) Inventors: Alireza Marandi, Pasadena, CA (US); Luis M. Ledezma, La Crescenta, CA (US); Louise E. Schul, Columbia, MO (US); Selina Zhou, Pasadena, CA (US)

(73) Assignee: California Institute of Technology, Pasadena, CA (US)

(21) Appl. No.: 18/612,461

(22) Filed: Mar. 21, 2024

Related U.S. Application Data
(60) Provisional application No. 63/453,642, filed on Mar. 21, 2023.

(51) Int. Cl. H01S 5/183; H01S 5/04; H01S 5/20

(52) U.S. Cl. CPC H01S 5/18327; H01S 5/041; H01S 5/2018

(57) ABSTRACT

A device including a chip including a photonic integrated circuit comprising an external cavity for a source of electromagnetic radiation; the source of electromagnetic radiation attached to a top surface of the chip, the source comprising a semiconductor active region comprising, or coupled to, an output for the electromagnetic radiation, wherein the output is oriented to emit the electromagnetic radiation into the top surface in an emission direction that is inclined with respect to a plane of propagation of the electromagnetic radiation in the external cavity; and a coupler coupling the active region to the external cavity via the top surface to integrate the external cavity with the active region. The coupler partially couples the electromagnetic radiation outputted from the active region to the external cavity, and feedback from the external cavity to the active region.

### CROSS-REFERENCE TO RELATED APPLICATIONS

This application claims the benefit under 35 U.S.C. Section 119 (e) of U.S. Provisional Application No. 63/453,642 filed Mar. 21, 2023, by Alireza Marandi, Luis. M. Ledezma, Louise E. Schul, and Selina Zhou, entitled “SURFACE-COUPLED INTEGRATED-CAVITY SEMICONDUCTOR LASER,” (CIT-8982-P), which application is incorporated by reference herein.

### STATEMENT REGARDING FEDERALLY SPONSORED RESEARCH AND DEVELOPMENT

This invention was made with government support under Grants No. FA9550-20-1-0040 and FA9550-23-1-0755 awarded by the Air Force and under Grant No. ECCS1846273 awarded by the National Science Foundation. The government has certain rights in the invention.

### BACKGROUND OF THE INVENTION

### Field of the Invention

The present disclosure relates to emitters integrated with photonic integrated circuits and methods of making the same.

### Description of the Related Art

Tunable coherent sources are desirable in nanophotonics for a large number of applications including sensing, lidar, and telecommunications. Commercially available semiconductor lasers offer low cost but offer very limited tunability. What is needed then, are semiconductor emitters with improved performance (including tunability). The present invention satisfies this need.

### SUMMARY OF THE INVENTION

The present disclosure describes devices integrating a semiconductor emitter on the surface of a photonic chip. The emission direction of the semiconductor emitter is different from (e.g., 90+/−45 degrees with respect to) the direction of propagation on the photonic chip, and the spatial and spectral characteristics of the laser radiation can be engineered through a feedback mechanism provided by the photonic chip to the semiconductor emitter through (e.g., vertical) coupling between the emitter and the chip. The semiconductor emitter (e.g., vertically) coupled to the surface of the photonic chip can be any of one of the existing family of devices that includes, but is not limited to, vertical cavity semiconductor lasers (VCSEL), Fabry-Perot lasers, distributed feedback lasers (DFB), distributed Bragg reflector lasers (DBR), and even devices producing only spontaneous emission without lasing, like semiconductor gain chips and light emitting diodes (LEDs).

The invention provides routes to realization of high-power, tunable, mode-locked, and/or highly coherent semiconductor lasers in integrated photonic circuits. It also enables scalable manufacturing through relatively low-precision integration of semiconductor emitters with integrated photonic circuits, opportunities for better thermal management of integrated semiconductor lasers, increased damage thresholds for coupling interfaces, and long-term stability of semiconductor lasers.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

Referring now to the drawings in which like reference numbers represent corresponding parts throughout:

FIG. 1. The concept of surface coupled integrated emitter (e.g., laser).

FIG. 2. Example embodiment 1. A grating coupler on the surface of a photonic chip directs the light from an emitter onto a nanophotonic waveguide. A loop mirror provides feedback. The total feedback phase can be modified with on-chip actuators. The laser output can be coupled off-chip or can be used by other components on the same chip

FIG. 3. Example embodiment 2. A Bragg reflector is used at one side of the waveguide to provide feedback to the emitter. The total feedback phase, and the resonant frequency of the laser cavity can be modified with on-chip actuators. The laser output can be coupled off-chip or can be used by other components on the same chip.

FIGS. 4a-4c. Example of working principle. FIG. 4a: A grating coupler directs light from an emitter to a nanophotonic waveguide in possibly a large number of spatial and frequency modes. The on-chip components provide optical feedback only on the desired single mode, or a desired number of modes, forming an external integrated cavity laser. FIG. 4b: The feedback induces stronger stimulated emission on the emitter decreasing the energy content emitted in the undesired modes. FIG. 4c: At steady state, most of the energy emitted by the emitter is contained on the desired modes that are selected by the feedback from the photonic chip, i.e. the external cavity of the laser.

FIG. 5. Top view (top) and size view (side) schematic of the example implementation. Top: The original VCSEL (not pictured here) beam is reduced to an ˜35 μm mode field diameter (MFD) beam on the grating region using a gradient index micro lens (GRIN lens), and the adiabatic taper further confines the mode to that of a single-mode waveguide. The loop mirror acts as the output coupler of the laser cavity and provides single-mode feedback to the VCSEL. Bottom: The VCSEL, GRIN lens, grating coupler, single-mode waveguide, and loop mirror form the laser cavity, providing single mode feedback to the VCSEL

FIGS. 6a and 6b show a photo (FIG. 6a) and layout (FIG. 6b) of on-chip devices comprising an integrated laser, including test structures for calibrating fabrication recipes. FIG. 6c shows the experimental setup. The VCSEL is mounted on top of the chip surface, and the laser output is fiber coupled to OSAs and photodetectors for characterization

FIG. 7. Simulation setup for grating coupler parameter optimization using Ansys Lumerical Finite Distance Time Domain (FDTD).

FIG. 8. Apodized grating couplers TE0 transmission as a function of wavelength, at different minimum feature sizes.

FIGS. 9a-9c. 2D parameter sweeps for grating coupler designs, colorbar shows fundamental TE mode (TE0) transmission into the single mode waveguide. FIG. 9a: Using 976 nm source, after optimizing source position and incidence angle (theta), a 2D parameter sweep of the grating pitch and etch depth are performed, for a even grating design. The star indicates the maximum TE0 transmission value of 34%, corresponding to an etch depth of 190 nm. FIG. 9b: Fixing etch depth at 190 nm, for the 940 nm source, a 2D parameter sweep of pitch vs. source angle is performed for the even grating design. The maximum TE0 transmission (indicated by the star) is 45.3%. FIG. 9c: For the apodized grating design for 940 nm source, 2D parameter sweep for apodization factor R and etch depth shows that 190 nm etch depth is a reasonable value.

FIG. 10. Loop mirror designs using adiabatic couplers. Figures show the power coupling as a function of wavelength for the three single-mode waveguide widths used in the example implementation. Widths, L, and gap are defined in FIG. 10.

FIG. 11. Schematic of an adiabatic coupler for the loop mirror. Region between the dashed lines is the coupling region, with length L. W1 and W3 are the widths of straight waveguide sections on the left side of the coupling region, and W2 is the waveguide width of the loop mirror, W2=(W1+W3)/2.

FIG. 12. Flowchart illustrating a method of fabricating a device.

Some of the drawings are better understood when provided in color and the specification makes reference to color versions of the drawings. Applicant considers the color versions of the drawings as part of the original disclosure and reserves the right to provide color versions of the drawings in later proceedings.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

### Technical Description

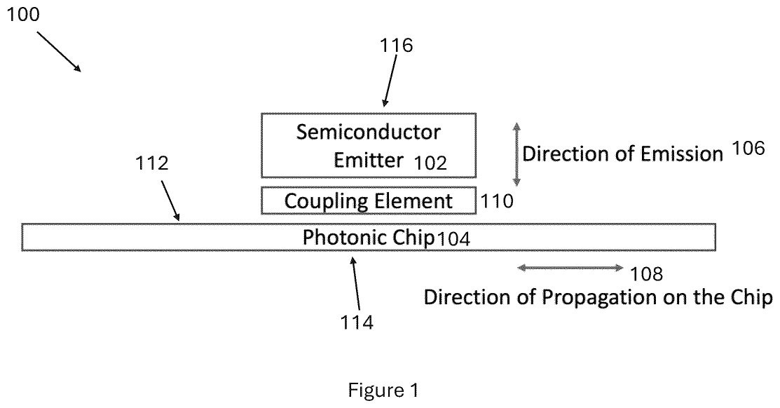

FIG. 1 illustrates a concept and general device 100 comprising a (e.g., semiconductor) emitter 102 (e.g., a laser), a photonic chip 104 which includes parts of the cavity of the emitter, and/or an additional external cavity, wherein the direction of emission 106 of the emitter and the direction of propagation 108 in the photonic chip are different (e.g., by 90 degrees+/−45 degrees); and a coupling element 110 that directs the emission 106 from the emitter into the chip and back.

Generally, the size of the coupling region on the emitter is typically associated with multiple spatial modes. The coupling elements include one or a combination of a grating coupler, metasurface, and/or inverse-designed structure to provide appropriate coupling between the circuit on the chip and the emitter [1-2]. These coupling elements can be realized on the semiconductor emitter, or the photonic chip, and/or as a separate components. Design of the grating coupler is discussed in following sections. The coupling element can further include bulk optical components such as lenses.

The semiconductor emitter includes one, or a combination of, or a plurality of a Vertical cavity semiconductor laser (VCSEL), Vertical external cavity semiconductor lasers (VECSEL), edge-emitting Fabry-Perot laser, Edge-emitting distributed feedback laser (DFB), edge-emitting distributed Bragg lasers (DBR), edge-emitting gain chip, edge-emitting light emitting diodes, or ptically pumped semiconductor gain element. Typical emitter materials include, but are not limited to semiconductors such as III-V semiconductors or semiconductors comprising biased p-n junctions comprising e.g., GaAs, AlGaAs, InP, GaN, AlGaN, InAlGaN, InGaN wherein electromagnetic radiation is emitted by recombination of holes and electrons injected into the device or by optical pumping. Typical emission wavelengths include, but are not limited to visible through infrared, e.g., 400 nm-10 microns, and typically communication wavelengths between 800 nm and 2 microns.

The photonic chip includes a waveguide that could be single mode or multimode at the target wavelength as a part of the laser cavity and/or an additional cavity to provide feedback to the emitter. Example materials for the photonic chip and the waveguides include, but are not limited to, silicon, lithium niobate, silicon nitride, e.g., formed on an oxide underlayer. The waveguide can be defined by etching the waveguide shape/cross-section into the chip material.

The photonic chip can include other components in the cavity of the laser/emitter for controlling the laser/emitter operation including but not limited to at least of an actuator, an integrated mirror in the photonic chip to provide optical feedback to the semiconductor laser, one or more components and one or more circuits for active and/or passive mode-locking, and/or one or more components and one or more circuits for wavelength conversion.

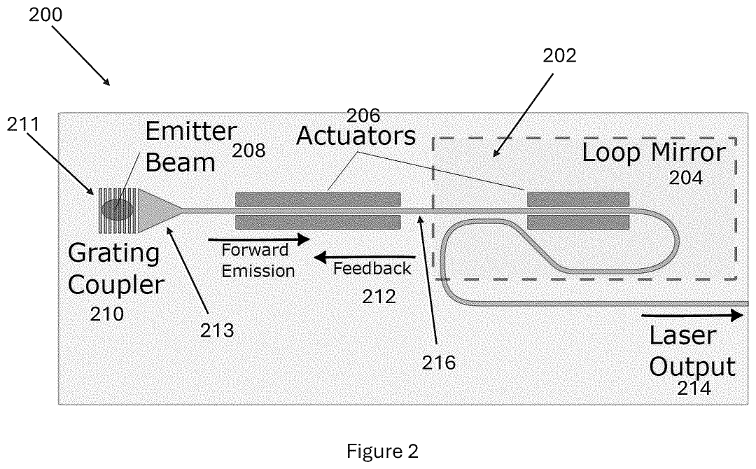

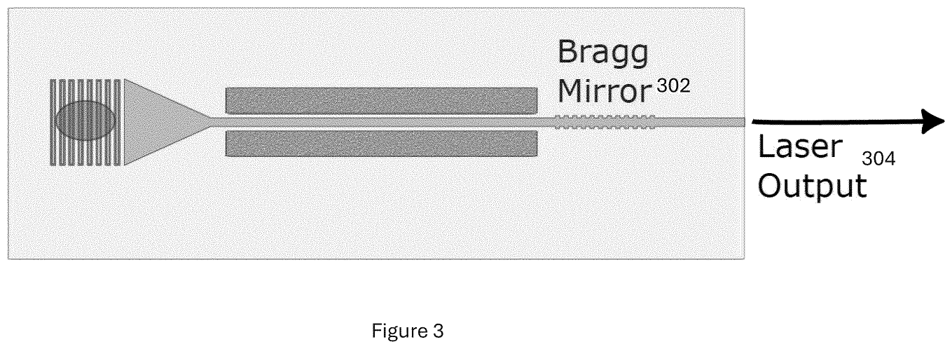

The mirror could be any of the following different types, including but not limited to, a loop mirror (FIG. 2), a Bragg grating mirror (FIG. 3), an inverse-designed mirror, or resonator(s) and/or an array of resonators.

The photonic chip can comprise one or more actuators (to control some parameters in the cavity of the laser including the phase and intensity). An example actuator includes, but is not limited to, an electro-optic modulator or a thermo-optic modulator.

The photonic chip a component and circuit for active and/or passive mode-locking, or a component and a circuit for wavelength conversion. Any combination of one or more of these components can be implemented.

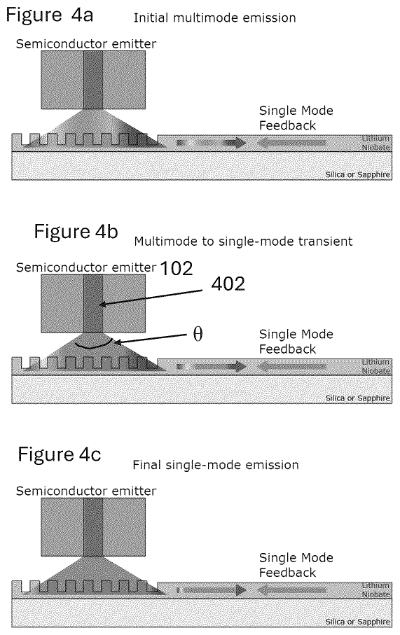

In one example, a single mode laser can be obtained by starting from a multimode emitter (FIG. 4). The laser wavelength can be tuned and/or locked using the components on the photonic chip. A high-power integrated semiconductor mode-locked laser can be realized using the mode-locking circuit components described in [3]. The photonic chip can also include an optical parametric oscillator [4], for which the laser can be used as a pump.

The mechanism for the operation of the laser can be either a single extended cavity laser, where the laser cavity includes parts of the circuit on the chip and/or multiple cavities. For instance, the emitter can have one cavity for lasing, for instance a VCSEL with a fabry-perot cavity on the same chip, and an additional feedback mechanism on the photonic chip to provide self-injection locking. The self-injection locking can be used for a variety of functionalities such as wavelength tuning and/or mode locking of the emitter.

Moreover, the output of the laser can be used at different points in the schematic of FIG. 1. In one configuration, the output can be mainly on the chip driving a photonic integrated circuit on the chip. In other configurations, the laser/emitter can have additional outputs. For instance, one output of the laser/emitter can be from the surface of the emitter that is not contacting the coupling elements. Another variation is to have the output of the laser/emitter passing through the photonic chip exiting downwards in FIG. 1.

### Example Applications Configurations or Feedback Functionality

The tunability of lasers can be greatly improved by combining them with photonic integrated chips that provide custom feedback capable of modifying the lasing characteristics of the entire system. The semiconductor laser and the photonic integrated chip can be combined using lateral (i.e. edge) coupling, in which both chips are placed side by side, or vertical (i.e. surface) coupling, in which the output of the semiconductor laser impinges vertically onto the photonic integrated circuit.

The present invention describes the design and fabrication of an external cavity, or extended cavity, semiconductor emitter using surface coupling to a photonic integrated circuit. Surface coupling to photonic integrated circuits can be used for large-area emitters typically considered multi spatial mode emitters if used standalone. When the laser cavity is extended into the photonic chip, much higher powers can be delivered to the chip compared with small-area emitters while the operation of the laser can still be single mode through the feedback provided by the components and circuitry on the photonic chip. Lateral coupling is typically sensitive to alignment requiring tight tolerances on the order of nanometers unless the modes of the emitter and photonic circuits are spatially matched to each other. However, surface coupling can alleviate the alignment and manufacturing tolerances to the micrometer regime and is therefore preferred from a manufacturing perspective.

As described herein, the surface-integrated scheme can be used for typical surface emitting semiconductor lasers, such as VCSELs, as well as edge emitting devices which can be vertically coupled through the surface of photonic chips by mounting them orthogonally to the chip surface.

The physical basis of the scheme for modifying the spatial and spectral emission of semiconductor emitters can be explained in reference to FIG. 4:
a) The semiconductor emitter provides light in a multitude of transversal and longitudinal modes if used standalone. The photonic chip provides stronger feedback on the desired modes.
b) Stimulated emission on the feedback modes increases the power emitted by the laser into the desired modes while decreasing the energy going into competing modes.
c) Under steady state conditions, most of the power emitted by the emitter would be on the modes that are feedback by our photonic chip.
Additionally, this concept can also be applied to a laser structure with multiple feedback mechanisms through self-injection locking. In such a case, the emitter can have its own cavity and provide lasing, while the extended cavity provides additional feedback that can further select the spatial and/or spectral mode of the laser and provide a mechanism for additional coherence, tuning, and/or mode locking.

### Example Fabricated Implementation

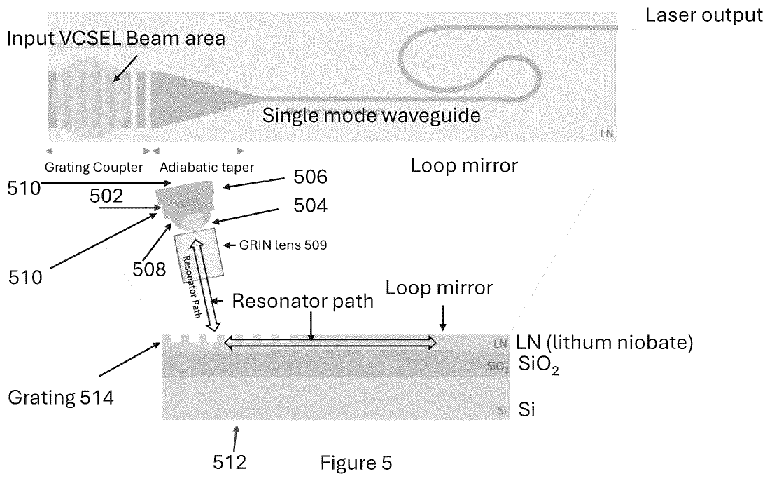

The following example implementation was manufactured to extract a single transverse mode, on-chip source from a surface-coupled multimode VCSEL (QT Brightek QBHP684E-V940Y2). Compared to edge emitting lasers, VCSELs offer several advantages such as on-wafer testing, high optical power, and circular beam geometry. The surface coupler used in this example is a grating coupler, which converts a free-space gaussian input beam to a fundamental TE mode on chip. As shown in FIG. 5, the VCSEL (945 nm wavelength, ˜1 mm mode field diameter, 1 W optical power) was aligned to the grating coupler region of a 300 nm thin-film lithium niobate photonic chip. The original mode area of the VCSEL was reduced using a gradient-index lens (GRIN) to improve overall coupling efficiency (not pictured). The grating coupler region was 35 micrometers by 35 micrometers to accommodate the reduced beam spot size, and the adiabatic taper further confines the on-chip mode to the size of the single-mode waveguide. The loop mirror acts as the output coupler of the laser cavity and provides single-mode feedback to the VCSEL.

The GRIN lens and VCSEL are placed at a slight angle to maximize transmission. As shown in FIG. 5 (bottom), the VCSEL, GRIN lens, grating coupler, single-mode waveguide, and loop mirror forms a laser resonator that provides single mode feedback to the VCSEL cavity. The two mirrors of the laser cavity are the back bragg mirror within the VCSEL and the on-chip loop mirror.

Several parameters were considered in the design of the laser system, including the grating coupler efficiency, taper loss, waveguide geometry, and loop mirror reflectivity. In FDTD simulations, the grating coupler on our thin film lithium niobate (TFLN) platform can achieve fundamental TE transmission up to 76% using an apodized grating design, and 57% using an even periodic grating design [7]. In practice, measured transmission is also a function of the minimal achievable feature size of the grating patterns, which is determined by limitations in the fabrication process. The etch depth of all on-chip structures is fixed by the optimal design of the grating coupler. To minimize taper loss, the length of the taper was designed to be longer than the adiabatic length and verified via eigenmode expansion simulations. At a wavelength of 940 nm, the adiabatic length for tapering from 35 μm down to 1 μm was 2486 μm. Finally, the loop mirror reflectivity determines what percentage of power will be sent back to the VCSEL for feedback, and the remaining power can be sent to the laser output. For the first version of the device, 50:50 adiabatic couplers were designed and fabricated to achieve ˜99% feedback to the VCSEL.

The use of single-mode waveguides on chip is a critical design consideration, for the final output to act as a clean fundamental TE source for other on-chip photonic devices. For instance, if the width of the waveguides supports multiple TE modes at 940 nm, bends in the loop mirror can lead to mode-crossings, which would significantly reduce the overall coupling and feedback efficiency since the grating coupler is designed only for the fundamental TE mode. This results in another advantage of surface coupling over edge coupling, since the narrower the waveguide widths, the higher the insertion loss for edge coupling due to greater mode size mismatch.

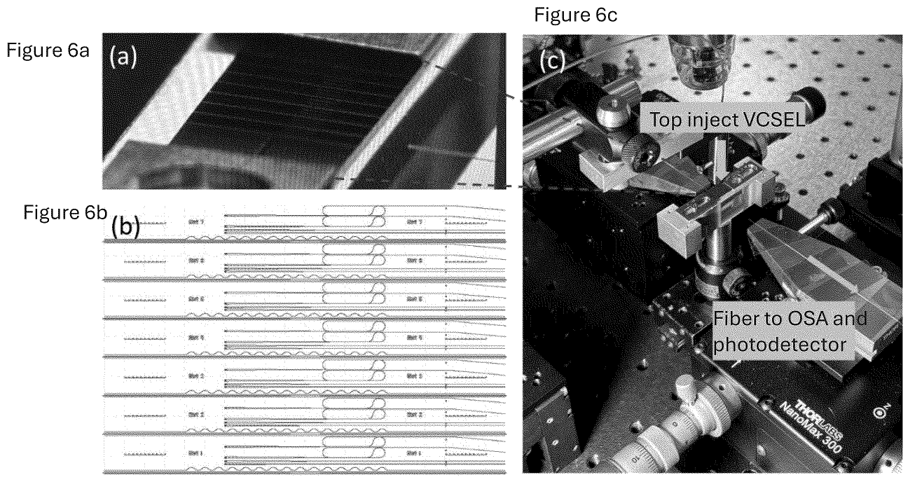

A photo and layout of the fabricated example implementation chip is shown in FIGS. 6(a) and (b). This version of the on-chip components includes structures designed for the VCSEL, as well as for a Fabry-Perot laser (976 nm wavelength, 900 mW) as test structures for grating characterization purposes. Each “Set” of grating structures contain two pairs of apodized design and even design of the grating couplers. Within each pair, one is connected to a loop mirror while the other is connected directly to a straight waveguide to the output. Across different sets, the waveguide width is varied from 400 nm to 1.8 μm. The VCSEL is soldered onto a custom PCB with a copper heatsink and mounted vertically on top of the chip, using a precision rotation mount to set the coupling angle. The output of the devices is fiber-coupled to the OSA and photodetector for characterization measurements. We measured ˜18 dB fiber-to-fiber insertion loss to characterize the expected loss at the fiber output. A summary of the target wavelengths and waveguide widths are presented in Table 1. Details on the design process for choosing these parameters will be discussed in the next section.

TABLE 1
Target wavelengths and waveguide widths for all 7 sets
of on-chip device structures, shown in FIG. 6(b). Note
that set 7 is a test structure since 1800 nm wide waveguide
supports multiple modes at 940 nm wavelength.

| Set # | Wavelength (nm) | Waveguide width (nm) |
|---|---|---|
| 1 | 940 | 400 |
| 2 | 976 | 400 |
| 3 | 940 | 775 |
| 4 | 976 | 775 |
| 5 | 940 | 945 |
| 6 | 976 | 945 |
| 7 | 940 | 1800 |

### Simulations of Grating Coupler, Loop Mirror Design, and Device Performance

The device of the example implementation was designed following the following procedures, and the on-chip components were (and can be) fabricated and tested as part of a recipe development process to achieve optimal coupling and feedback efficiency.

### (a) Grating Coupler Design

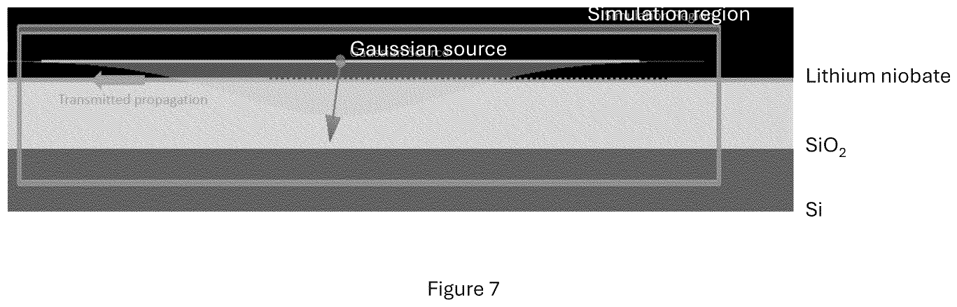

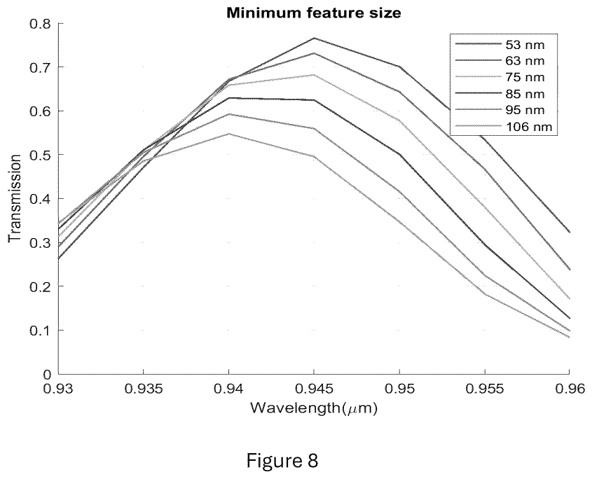

The grating coupler directs vertical beams from the VCSEL into the on-chip components. It also simultaneously acts as a transverse mode filter, converting an approximately Gaussian beam from the VCSEL in free space into a fundamental TE mode on-chip. We first determine an estimate of the grating design using the standard first order Bragg condition, which calculates the grating periodicity as a function of wavelength, effective refractive index, and coupling angle. We then perform various parameter sweeps using Ansys Lumerical FDTD, following a simulation setup shown in FIG. 7. A Gaussian Source with beam radius of 20 μm is placed 1 μm above the chip surface, and the lithium niobate grating region is 35 μm wide. A TE mode power monitor is placed at the end of the simulation region (after the green arrow) to capture the percentage of power coupled into the fundamental TE mode. Simulation parameters including the angle (theta) and position of the Gaussian source, etch depth, and grating period (pitch) are swept to optimize for fundamental TE mode transmission. For the apodized grating design, the duty cycle (or fill factor), F, of the grating teeth are linearly varied as a function of grating position, x, and set by an apodization factor R:

$$F = {F}_{0} - R \cdot x$$

where F₀ is an initial fill factor, limited by fabrication tolerances. For each grating tooth, a new period value is calculated using the Bragg condition,

$$Λ = \frac{λ}{{n}_{eff} - sin ( {θ}_{air} )}$$

where the effective index is a function of the fill factor. Hence, for the apodized design, we swept over additional parameters F₀ and R. As previously mentioned, the maximum achievable transmission is a function of F₀. As shown in FIG. 8, a F₀ of 0.9 corresponds to a minimum feature size of 53 nm, enabling maximum TE₀ transmission of 76% at 945 nm. If such minimum feature size is not achievable, the maximum transmission would become lower.

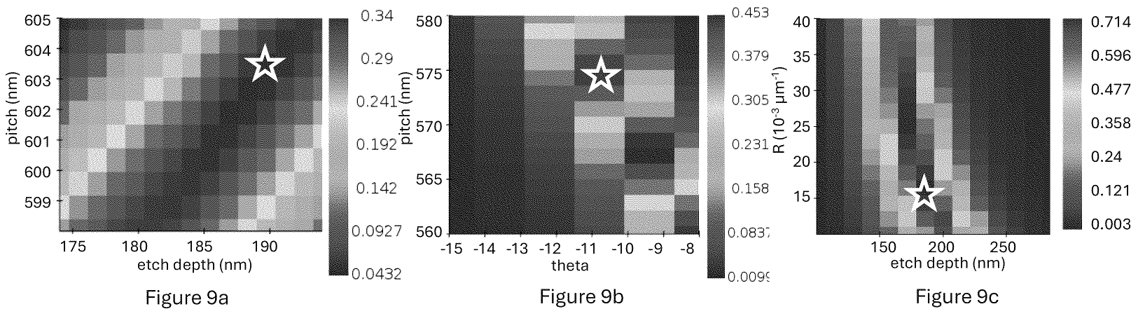

To simplify the etching step in fabrication, the etch depth of all on chip structures was designed to be the same value. This places limitation on the optimization process for the grating coupler structures since we need to accommodate two different wavelengths (940 nm and 976 nm) for both apodized and even grating designs. For the 976 nm source, a two dimensional (2D) parameter sweep of even grating period (pitch) and etch depth (etch) after optimizing source position and source incidence angle (theta) gave the maximum TE₀ mode transmission of 34% at an etch depth of 190 nm (FIG. 9a). Using this etch depth, we swept over pitch and theta using a 940 nm source, resulting in maximum TE₀ mode transmission of 45% (FIG. 9b). For the apodized design, using the 940 nm source (for VCSEL), a 2D parameter sweep of the apodization factor R and etch depth shows that the selected etch depth of 190 nm is a reasonable value. Another round of optimization sweeps is performed under the etch depth constraint to determine final parameter values. The final parameter values for three grating coupler designs on the example implementation chip is summarized in Table 2.

| | | Etch Depth | Pitch | Source Angle | | | |
|---|---|---|---|---|---|---|---|
| Wavelength (nm) | Design | (nm) | (nm) | (degrees) | FO (Fill factor) | R (μm − 1) | TEO transmission |
| 976 | Even | 190 | 603.5 | 9.6 | N/A | N/A | 34.5% |
| 940 | Even | 190 | 575.0 | 9.5 | N/A | N/A | 45.3% |
| 940 | Apodized | 190 | N/A | 9.5 | 0.9 | 0.0120 | 71% |

Table 2. Summary of final parameters for the grating couplers on the example implementation chip. Parameters optimize for maximum transmission from the VCSEL & GRIN lens to the on-chip waveguides.

### (b) On-Chip Cavity

The on-chip portion of the proposed laser cavity includes the grating coupler in section (a), a taper, a section of single mode waveguide, and a loop mirror. The taper length is designed to be slightly longer than the adiabatic length, which is between 2 mm to 2.5 mm for the various wavelengths and single mode waveguide structures in this example implementation. The total length of the cavity is irrelevant for spatial mode injection locking on this chip, hence no actuators are included in the design. If we also want to injection lock the frequency mode, then the external cavity length (including the distance from the emitter to the grating coupler) will need to be carefully designed to have a resonant frequency matching that of the emitter, in which case on-chip modulators can be used.

### (c) Loop Mirror Design

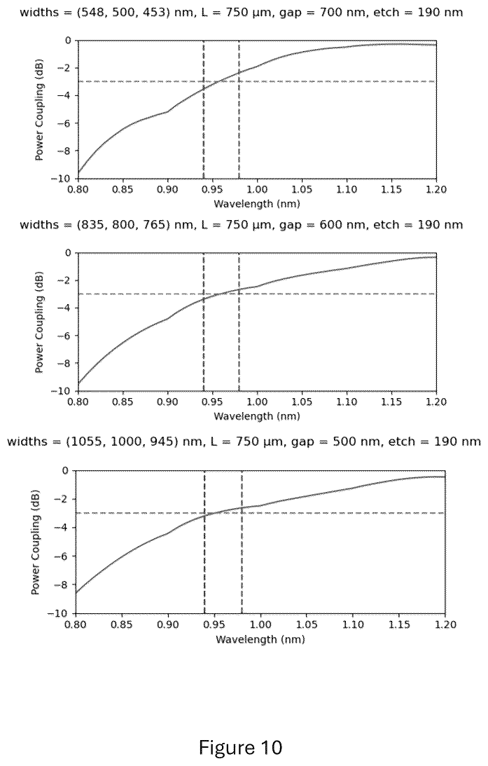

The loop mirror consists of a 50:50 adiabatic coupler, designed with coupled mode equation and verified in Ansys Lumerical Eigenmode Expansion software. The −3 dB power coupling region for a 1 μm wide waveguide is shown in FIG. 9. The parameters used in simulations are labeled in FIG. 10. In FIG. 9 (top), widths 548, 500, and 453 nm corresponds to W1, W2, and W3 in FIG. 10. L=750 μm is the length of the coupling region, and gap=700 nm is the gap between the two waveguides in the coupling region.

The performance of the fabricated chip integrated laser was estimated under ideal design parameters and fabrication conditions, assuming a grating coupler coupling efficiency of 76%, and a loop mirror reflectivity of 99%. If the VCSEL is operated at 1 W, assuming the grating coupler is symmetrical in both directions, 572 mW of TE 0 mode reflection will be sent back to the VCSEL. Assuming this amount of feedback is enough to lock emission modes of the VCSEL to the desired mode, we can expect mW level of optical power at the laser output, which can then be characterized (power and linewidth) to determine the effect of feedback mechanism. The loop mirror reflectivity needs to be varied to determine an optimal tradeoff between necessary feedback power and final output power, as the final goal of the proposed device. A linewidth narrowing observed on the output optical frequency spectrum and increase in fundamental TE mode power (compared to a no resonator case) indicates successful spatial mode injection locking.

### Advantages and Improvements

As described herein, the integration of a semiconductor emitter and a photonic chip via surface coupling, provides a method for incorporating both high power and high beam quality (in terms of spectral and spatial modes) laser for integrated photonic devices. Such surface coupling mechanism enables a low loss coupling of high-power emitters, typically with larger mode areas, to components on photonic chips with highly confined optical modes. Aside from better alignment tolerances, we outline two major advantages of the invention compared to other lasers for integrated photonics applications, namely higher on-chip power, and control for cleaner modes.

Stable laser emission with narrow linewidth and/or high peak power is often desired in optical systems, for example for applications in coherent communications, nonlinear optics, remote sensing, etc. Realization of such devices in on-chip platforms requires careful considerations of scalability, where the quality and cost of the laser source becomes critical. Semiconductor lasers became a competitive candidate for such applications due to their small package size, low power consumption, and economical pricing. However, high power and good beam quality often cannot be achieved simultaneously with conventional edge- or surface emitting semiconductor lasers. For instance, edge-emitting laser diodes can easily achieve tens of Watts of output power, but at the cost of elongated output beams with large aspect ratios; vertical-cavity surface-emitting lasers (VCSELs) can emit circular fundamental transverse mode beams at low power, but still becomes multi-mode at Watt-level output power, and scaling up power also scales up the beam size. Demand for low-cost, small footprint lasers with both high beam quality and high spectral purity drove efforts toward developing methods for modifying the spatial and spectral emission of semiconductor emitters. For example, vertical external-cavity surface-emitting (VECSELS) lasers have been demonstrated using a surface-emitting semiconductor gain chip and an external cavity, which typically consist of one or several external optical elements. As a free-space laser source, VECSELS have been shown to generate high optical powers with high beam quality.

The laser scheme described herein comprises of a semiconductor emitter, an on-chip component with some feedback mechanism, and a coupling element between the chip and the semiconductor emitter via surface coupling. By definition, surface coupling enables a direct placement of the emitter on top of the photonic chip, offering much higher alignment tolerances compared to other coupling such as edge coupling. To simplify packaging and improve durability, the point of contact between the emitter and the coupling element can also be tailored, for example using anno-scale 3D printing technology to create simpler lens systems. While edge coupling methods often require focusing high power on a small waveguide facet, surface coupling can work with a relatively larger area, which effectively increases the damage threshold for the interface and enables higher on chip power.

The coupling element connects the semiconductor emitter and the on-chip feedback components to form a cavity, enabling direct feedback to the emitter area to modify the quality of the laser output in terms of spatial and spectral modes. It has been extensively demonstrated in literature that self-injection locking can be achieved through locking the emissions of the semiconductor laser to one or more eigenmodes of an external cavity (such as a high-Q micro ring resonator), leading to a narrower linewidth and improved stabilization of the laser. In essence, the laser locks itself to a particular operating mode or frequency at steady state as the feedback increases the power emitted by the laser into desired modes, and simultaneously decreases the energy in competing modes. Similarly, when coupling a large area, multimode beam from the semiconductor via surface coupling (using gratings, metasurfaces, or other inverse-designed structure), the addition of a spatial mode filter component inside the cavity can lock the laser to the desired transverse mode via mode competition with other transverse modes. Furthermore, actuators such as electro-optics modulators and thermo-optic modulators can be placed within the cavity to control laser parameters.

Existing literature in self-injection locking via integrated photonics components uses edge-coupling methods, and there is no prior demonstration of self-injection of semiconductor lasers locking via surface coupling methods on such platforms. Surface coupling on integrated photonic chips have been used for input and/or output coupling, a relevant example being injection locking a slave VCSEL with a fiber-coupled tunable laser [5-6]. However, self-injection locking without the use of an additional seed laser has not been demonstrated on integrated photonics platforms via surface coupling. A major challenge for such realizations is the large transverse mode size mismatch between on-chip single mode waveguides and the semiconductor emitter, hence the threshold for achieve self-injection locking of the spatial mode is unclear.

In summary, a semiconductor emitter integrated via a surface coupling scheme to a p photonic integrated circuit, simultaneously enables the realization of high beam quality and high on-chip power. The system can be pumped by a readily accessible semiconductor laser/emitter, and its output acts as a single mode laser/emitter, in which the laser/emitter wavelength can be tuned or locked depending on the specific designs of the on-chip components.

### Process Steps

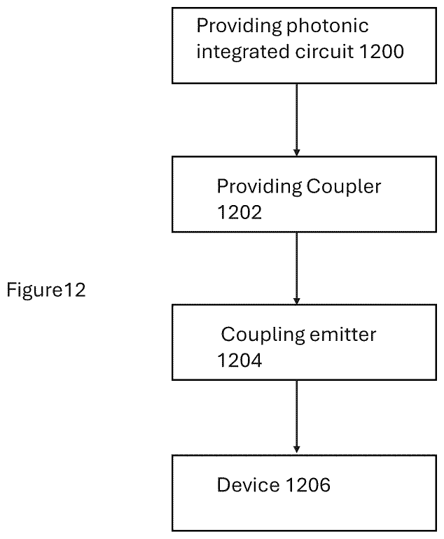

FIG. 12 is a flowchart illustrating a method of integrating an emitter to a photonic integrated circuit.

Block 1200 represents providing (e.g., designing and/or manufacturing) a photonic integrated circuit comprising a cavity for an emitter. In one or more embodiments, the cavity comprises a waveguide supporting a single fundamental mode (e.g., transverse electric TE₀₀ or TE₀) of the electromagnetic radiation emitted from the emitter coupled to a mirror or reflector. In one or more embodiments, the waveguide dimension (e.g., width) is selected so that only one fundamental spatial TE 0 mode is supported (in some embodiments, a width less than 1 micron satisfies this requirement of supporting only the transmission of the TE 0 mode). The waveguide dimensions, length, and mirror reflectivity can be designed for particular applications or desired feedback, be it injection locking, mode locking etc. In some embodiments, the cavity length (and therefore the waveguide length) is selected to match the free spectral range of the cavity to that of the desired modes being fed back. The cavity in photonic integrated circuit can comprise one or more outputs to output the electromagnetic radiation outputted from the emitter (after the feedback functionalizing the emitter performance) off the chip or to other components of the photonic integrated circuit.

In various examples, the cavity may comprise and actuator, e.g., modulator comprising material (e.g., liquid crystal or nonlinear material, or electro-optic material, or thermo-optic material) thermally or electrically coupled to an electrode, wherein application of a voltage to the electrode controls, e.g., resistive heating, piezoelectric actuation, bi refringence, or electro-optic actuation of the material so as to control a phase or amplitude of the electromagnetic field of the optical pulses passing through the material. For example, an actuator can comprise any electro-optic modulators (EOMs), acousto-optic modulators (AOMs), heaters, or any on-chip and/or off-chip device and/or mechanism used to dynamically change the refractive index of any portion of the device. Any combination of actuators may be used individually from each other and/or in conjunction with each other to perform certain dynamic alterations that allow for control over the electromagnetic radiation.

In some embodiments, the photonic integrated circuit further comprise optical parametric oscillators or other resonators coupled to an output of the cavity, e.g., as described in [8].

The photonic integrated circuit can be formed (e.g., etched) in a chip material comprising, but not limited to, lithium niobate, silicon, silicon nitride, or other suitable material.

Block 1202 represents providing (e.g., designing and/or manufacturing) a coupling or coupling element to couple the semiconductor emitter to the cavity. The coupling can be designed to maximize transmission of the electromagnetic radiation outputted from the semiconductor emitter into the waveguide (e.g., at least 60% transmission). Example couplings include, but are not limited to, a diffraction grating, or grating couplers or a metasurface (e.g., comprising an array of antennas or other scattering elements) that couple electromagnetic radiation from the emitter into the waveguide, e.g., by a scattering, diffraction, or interference process. The coupling can be designed to match the mode of the electromagnetic radiation emitted from semiconductor emitter to the mode of waveguide. For example, in the case of a grating coupler, grating parameters comprising at least one of the periodicity/apodization, grating spacing, grating width can be selected to shape the mode of the semiconductor emitter into a mode compatible with (e.g., a gaussian mode) of the waveguide. The grating parameters are selected based on the beam size, divergence, and wavelength of the electromagnetic radiation outputted from the emitter, e.g., grating spacing and width can be in a range of 10 nm-100 nm.

In some embodiments, the coupling can further include focusing means (e.g., one or more lenses or mirrors) that collimate or focus the beam size outputted from the emitter. In some cases, the beam cross-section emitted from the emitter can have an area of at least 100 microns by 100 microns, and the focusing means can focus the beam outputted from the emitter to an area of 20 microns by 20 microns or less to match the area of the grating/grating coupler.

In some embodiments, the output from the emitter (e.g., edge emitter) is a stripe or elliptical shape beam, and the coupler comprising at least one of the focusing means or the grating/metasurface shapes the beam into a gaussian shaped spatial mode.

Block 1204 represents coupling the emitter to the chip using the coupling. As described herein, an example emitter can comprise, but is not limited to, a laser, a light emitting device, or semiconductor optical amplifier.

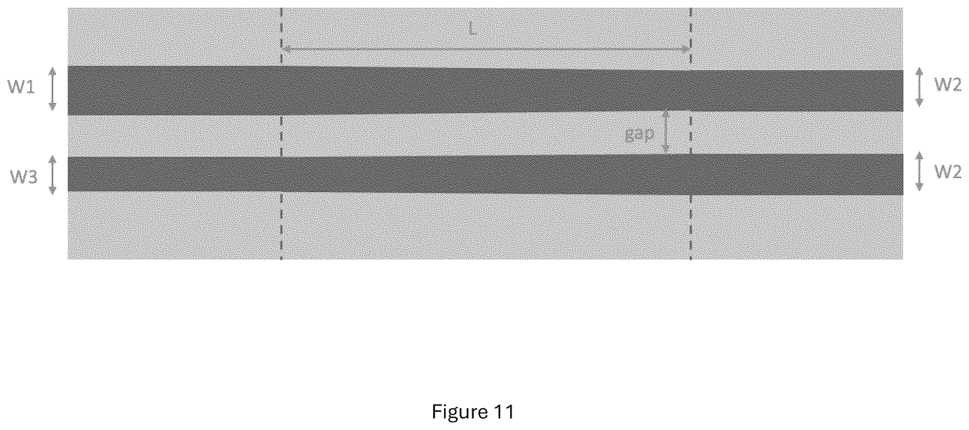

Block 1206 represents the end result, a device comprising an emitter integrated with a photonic integrated circuit/cavity. Illustrative embodiments include, but are not limited to, the following (referring also to FIGS. 1-11).

1. A device 100, comprising:
a chip 104 comprising a photonic integrated circuit 200 comprising an external cavity 202 for a source 102 of electromagnetic radiation 208;
the source 102 of electromagnetic radiation 208 attached to a top surface 112 of the chip, the source comprising a semiconductor active region 502, 402 comprising, or coupled to, an output 504 for the electromagnetic radiation 208, wherein the output is oriented to emit the electromagnetic radiation into the top surface 112 in an emission direction 106 that is inclined with respect to a plane of propagation 108 of the electromagnetic radiation in the external cavity; and
a coupler 110 coupling the active region to the external cavity via the top surface to integrate the external cavity with the active region, wherein:
the coupler partially couples:
the electromagnetic radiation 208 outputted from the active region to the external cavity, and
feedback 212 from the external cavity to the active region.

2. The device of example 1, wherein emission direction is at an angle θ in a range-45 degrees≤θ≤+45 degrees with respect to the plane 108 of propagation.

3. The device of example 1 or 2, wherein the feedback tunes at least one of a spectral characteristic or spatial characteristic of the electromagnetic radiation.

4. The device of any one of the examples 1-3, wherein the external cavity comprises a waveguide 216 coupled to at least one component selected from a mirror 204, an actuator 206, a modulator 206, or an optical parametric oscillator.

5. The device of example 4, wherein the at least one component forms the feedback 212 mode-locking the source 102.

6. The device of any of the examples 3-5, wherein the actuator modulates the external cavity to mode-lock of the source 102.

7 The device of any of the examples 3-6, wherein the external cavity is configured to provide the feedback 212 comprising multiple modes for mode-locking the source 102 or to provide the feedback for spectrally narrowing the electromagnetic radiation 208.

8 The device of any of the examples 3-7, wherein the at least one component forms the feedback 212 changing a wavelength of the electromagnetic radiation so as to form the source comprising a tunable source.

9. The device of any of the examples 3-8, wherein the actuator is configured to form the feedback comprising the electromagnetic radiation having a modified phase.

10. The device of any of the examples 3-9, wherein the at least one component forms the feedback comprising one or more selected modes of the electromagnetic radiation.

11. The device of any of the examples 3-10, wherein the mirror comprises a Bragg mirror 302, a loop mirror 204, an inverse designed mirror, or a resonator.

12. The device of any of the examples 3-11, wherein the photonic integrated circuit comprises an optical parametric oscillator and the electromagnetic radiation is a pump for the optical parametric oscillator.

13. The device of any of the examples 1-12, wherein the coupler comprises a grating coupler 210 (e.g., comprising gratings 211 or diffraction gratings), a metasurface, or an inverse designed structure.

14. The device of example of any of the examples 1-13, wherein the source comprises a VCSEL 506, a VECSEL, an edge emitting laser, a semiconductor optical amplifier, or a light emitting diode.

15. The device of any of the examples 1-14, wherein the source comprises an edge emitting laser comprising a first end facet and a second end facet opposite the first end facet, wherein the laser attaches to the top surface via the first end facet comprising the output.

16. The device of any of the examples 1-15, wherein the external cavity comprises a circuit output 214, 304 outputting the electromagnetic radiation to a remainder of the photonic integrated circuit.

17. The device of any of the examples 1-16, wherein the source comprises a device output outputting the electromagnetic radiation from the device in a direction inclined with respect to the top surface.

18. The device of any of the examples 1-17, wherein one or a plurality of additional optical components are used in between the emitter and the coupler, such as one or more lenses 508, one or more diffractive components, one or more GRIN lenses 509, and/or polarization rotation optical components (or a combination thereof).

19. The device of any of the examples 1-18, wherein the feedback from the external cavity is complementing an internal cavity 510 of the source 102 of radiation, for instance by providing self-injection locking of the spectral and/or spatial mode of the source of radiation.

20. The device of any of the examples 1-19, wherein the radiation additionally outputs from the back 116, 510 of the source 102 and/or the bottom 114, 512 of the photonic chip 104.

21. The device of any of the examples 1-20, wherein the coupler comprises diffracting means (e.g., a grating or grating coupler), scattering means, or interference means to transmit the electromagnetic radiation between the source and the cavity, so that the coupler transmits at least 50%, 60%, 70%, 80%, 80%, or 50%-80% of the electromagnetic radiation between the source and the cavity.

22. The device of any of the examples 1-21, further comprising focusing means (e.g., one or more lenses 504, 509), or the coupler comprising focusing means, to focus the electromagnetic radiation onto the coupler so as to match, shape, or optimally overlap, a spatial mode and/or area of a beam 208 of the electromagnetic radiation with an area (e.g., grating surface) of the coupler coupling the electromagnetic radiation, e.g., so that the beam and the area of the coupler are commensurate in size/area.

23. The device of any of the examples 1-22, wherein the coupler comprises a grating or grating coupler or a metasurface, and the area comprises gratings for diffracting the electromagnetic radiation or elements (e.g., antennas) for scattering the electromagnetic radiation.

24. The device of any of the examples 1-23, wherein the coupler comprising a grating or grating coupler comprises a number of the gratings, a spacing of the gratings, a width of the gratings, or an apodization of the gratings 211 selected to match a spatial mode/area 208 of the electromagnetic radiation with a spatial mode (e.g., gaussian mode) of the waveguide in the cavity, and/or transmit (e.g., a first order diffraction of) the electromagnetic radiation into a waveguide of the cavity, e.g., to obtain the desired transmission.

25 The device of any of the examples 1-24, wherein the waveguide of the cavity is dimensioned to transmit and support only a fundamental TE0 mode of the electromagnetic radiation (no higher order modes).

26. The device of any of the examples 22-25, wherein the focusing means (e.g., one or more lenses) are selected to match/overlap a spatial mode (e.g., stripe or elliptical beam, gaussian) of the electromagnetic radiation with a spatial mode (e.g., gaussian mode) of the coupler, e.g., to obtain the desired transmission.

27. The device of any of the examples 1-26, wherein the coupler (e.g., grating/grating coupler) is formed or etched into the top surface of the chip and/or is part of the photonic integrated circuit.

28. The device of any of the examples 1-27, wherein the coupler comprises a grating coupled to an adiabatic taper 213 tapering into the waveguide 216 of the cavity.

29. The device of any of the examples 22-28, wherein at least one of the focusing means, the coupler, or the cavity perform spatial mode filtering of the electromagnetic radiation so that the electromagnetic radiation comprises a single spatial mode.

30. The device of any of the examples 1-29, wherein the coupler and cavity are tailored or designed for the electromagnetic radiation having one or more wavelengths in a range of 400 nanometers (nm)-10 microns, e.g., 800 nm-1.6 microns.

31. A device comprising a laser or semiconductor emitter physically attached to a top surface a chip comprising a photonic integrated circuit comprising a cavity, wherein the output of the laser is surface coupled and integrated with the cavity via a grating or scattering means.

32 The device of example 31 comprising the components of any of the embodiments 2-30.

33. A method of making a device, comprising
Providing a chip 104 comprising a photonic integrated circuit 200 comprising an external cavity 202 for a source 102 of electromagnetic radiation 208;
providing the source 102 of electromagnetic radiation 208 for attaching to a top surface 112 of the chip, the source comprising a semiconductor active region 502, 402 comprising, or coupled to, an output 504 for the electromagnetic radiation 208, wherein the output is oriented to emit the electromagnetic radiation into the top surface 112 in an emission direction 106 that is inclined with respect to a plane of propagation 108 of the electromagnetic radiation in the external cavity; and
coupling 110 the active region to the external cavity via the top surface using a coupler to integrate the external cavity with the active region, wherein:
the coupler partially couples:
the electromagnetic radiation 208 outputted from the active region to the external cavity, and feedback 212 from the external cavity to the active region.

34. The method of example 21 used to manufacture the device of any of the embodiments 1-32.

35. The method or the device of any of the examples 1-34, wherein the source of electromagnetic radiation comprises an electrically injected (e.g., light) emitting device or laser that emits the electromagnetic radiation in response to electrical injection or a voltage bias or electrical current (e.g., not optically pumped or seeded).

36. The method or the device of any of the examples 1-35, wherein the coupler comprises a grating or grating coupler comprising gratings 514 with a period, pitch, or spacing between gratings 514 in a range of 10 nm-1000 nm, a width of each of the gratings in a range of 10-1000 nm, and depth of each of the gratings (etch depth) in a range of 10 nm-1000 nm

### REFERENCES

The following references are incorporated by reference herein.
[1] Diyang Gu, Chenhui Liang, Libin Sun, Hang Chen, Yuan Chen, and Liu Yang, “Optical metasurfaces for waveguide couplers with uniform efficiencies at RGB wavelengths,” Opt. Express 29, 29149-29164 (2021)
[2] Piggott, A., Lu, J., Babinec, T. et al. Inverse design and implementation of a wavelength demultiplexing grating coupler. Sci Rep 4, 7210 (2014). https://doi.org/10.1038/srep07210
[3] Q. Guo, A. Marandi, “Chip-integrated mode-locked lasers based on thin-film nonlinear waveguides,” U.S. application Ser. No. 17/500,425
[4] A Marandi, L Ledezma, Y Xu, R M Briggs, “Thin-film optical parametric oscillators,” U.S. Pat. No. 11,226,538.
[5] Y. Yang, H. Lei, and Y. Huang, “A Low-Loss High-Directionality Grating Coupler for Integration of An Injection-Locked VCSEL on Silicon Photonics,” in Asia Communications and Photonics Conference International Conference on Information Photonics and Optical Communications 2020 (ACP/IPOC), OSA Technical Digest (Optica Publishing Group, 2020), paper M4A.157.
[6] Voloshin, A. S., Kondratiev, N. M., Lihachev, G. V. et al. Dynamics of soliton self-injection locking in optical microresonators. Nat Common 12, 235 (2021). https://doi.org/10.1038/s41467-020-20196-y
[7] Marchetti, R., Lacava, C., Khokhar, A. et al. High-efficiency grating-couplers: demonstration of a new design strategy. Sci Rep 7, 16670 (2017). https://doi.org/10.1038/s41598-017-16505-z
[8] U.S. patent application Ser. No. 18/543,950 by Ledezma et al., entitled ON-CHIP OPTICAL SYNTHESIZER OR Ledezma, Luis M. (2023) Towards Universal Integrated Laser Sources with Nonlinear Photonics. Dissertation (Ph.D.), California Institute of Technology. doi: 10.7907/ag5t-r511. https://resolver.caltech.edu/CaltechTHESIS:05242023-033922764.
[9] https://www.digikey.com/en/products/detail/qt-brightek-qtb/QBHP684E-V940Y2/11205089

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A device, comprising:
a chip comprising a photonic integrated circuit comprising an external cavity for a source of electromagnetic radiation;
the source of electromagnetic radiation attached to a top surface of the chip, the source comprising a semiconductor active region comprising, or coupled to, an output for the electromagnetic radiation, wherein the output is oriented to emit the electromagnetic radiation into the top surface in an emission direction that is inclined with respect to a plane of propagation of the electromagnetic radiation in the external cavity; and
a coupler coupling the active region to the external cavity via the top surface to integrate the external cavity with the active region, wherein:
the coupler partially couples:
the electromagnetic radiation outputted from the active region to the external cavity, and
feedback from the external cavity to the active region.

2. The device of claim 1, wherein emission direction is at an angle θ in a range −45 degrees≤θ≤+45 degrees with respect to the plane of propagation.

3. The device of claim 1, wherein the feedback tunes at least one of a spectral characteristic or spatial characteristic of the electromagnetic radiation.

4. The device of claim 1, wherein the external cavity comprises a waveguide coupled to at least one component selected from a mirror, an actuator, a modulator, or an optical parametric oscillator.

5. The device of claim 4, wherein the at least one component forms the feedback mode-locking the source.

6. The device of claim 4, wherein the actuator modulates the external cavity to mode-lock of the source.

7. The device of claim 4, wherein the external cavity is configured to provide the feedback comprising multiple modes for mode-locking the source or to provide the feedback for spectrally narrowing the electromagnetic radiation.

8. The device of claim 4, wherein the at least one component forms the feedback changing a wavelength of the electromagnetic radiation so as to form the source comprising a tunable source.

9. The device of claim 4, wherein the actuator is configured to form the feedback comprising the electromagnetic radiation having a modified phase.

10. The device of claim 4, wherein the at least one component forms the feedback comprising one or more selected modes of the electromagnetic radiation.

11. The device of claim 4, wherein the mirror comprises a Bragg mirror, a loop mirror, an inverse designed mirror, or a resonator.

12. The device of claim 1, wherein the photonic integrated circuit comprises an optical parametric oscillator and the electromagnetic radiation is a pump for the optical parametric oscillator.

13. The device of claim 1, wherein the coupler comprises a grating coupler, a metasurface, or an inverse designed structure.

14. The device of claim 1, wherein the source comprises a VCSEL, a VECSEL, an edge emitting laser, a semiconductor optical amplifier, or a light emitting diode.

15. The device of claim 1, wherein the source comprises an edge emitting laser comprising a first end facet and a second end facet opposite the first end facet, wherein the laser attaches to the top surface via the first end facet comprising the output.

16. The device of claim 1, wherein the external cavity comprises a circuit output outputting the electromagnetic radiation to a remainder of the photonic integrated circuit.

17. The device of claim 1, wherein the source comprises a device output outputting the electromagnetic radiation from the device in a direction inclined with respect to the top surface.

18. The device of claim 1, wherein one or a plurality of additional optical components are used in between the emitter and the coupler, the additional components comprising at least one of one or more lenses, one or more diffractive components, one or more GRIN lenses, or one or more polarization rotation optical components.

19. The device of claim 1, wherein the feedback from the external cavity is complementing an internal cavity of the source of radiation, by optionally providing self-injection locking of the spectral and/or spatial mode of the source of radiation.

20. The device of claim 1, wherein the radiation additionally outputs from the back of the source and/or the bottom of the photonic chip.
